(19) United States
(12) Patent Application Publication
(10) Pub. No.: US 2006/0246382 A1
(43) Pub. Date: Nov. 2, 2006

(54) Method for preparing semiconductor device

(75) Inventors: Geun Su Lee, Yongin-si (KR); Cheol Kyu Bok, Seoul (KR); Seung Chan Moon, Seoul (KR); Sung Koo Lee, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-shi (KR)

(21) Appl. No.: 11/312,107

(22) Filed: Dec. 20, 2005

(30) Foreign Application Priority Data
Apr. 27, 2005 (KR) 10-2005-0035126

(51) Int. Cl. G03F 7/26

(52) U.S. Cl. 430/331; 430/322; 430/330

(57) ABSTRACT

A method for reducing a photoresist pattern wherein, a photoresist film is formed, an aqueous composition comprising water and a surfactant is sprayed, and the pattern is treated by thermal energy to reduce the photoresist pattern uniformly and vertically, thereby improving an etching bias and enhancing process margins.

### BACKGROUND OF THE DISCLOSURE

1. Field of the Disclosure

The disclosure relates generally to a method for forming fine patterns of semiconductor devices. More specifically, the disclosure relates to a method for forming fine patterns of semiconductor devices including spraying an aqueous composition containing water and a surfactant onto a pattern before a post-baking step and heating the pattern to reduce spacing between the patterns.

2. Description of the Related Technology

As fabricating technology for semiconductor devices has advanced and the applied fields of memory devices have expanded, reduction in design sizes has accelerated as lithographic processes (e.g., the development of photoresist materials, new light exposure sources and related equipment) have improved, in order to develop memory devices of improved integrity.

However, since the resolution power obtained by the currently available KrF and ArF lasers is limited to 0.1 μm, it is difficult to form fine patterns for highly integrated semiconductor devices.

A resist flow process (hereinafter, referred to as “RFP”) is a representative method for forming a conventional fine pattern. With reference to FIG. 1, in the RFP, exposing and developing steps are performed onto an underlying layer 12 to form a photoresist pattern 14, of which the resolution is dependent upon the exposing light (see FIG. 1(a)). Thermal energy is then applied at a temperature above the glass transition temperature of the photoresist resin to cause thermal flow, thereby reducing the size of the photoresist pattern (see FIG. 1(b)).

Although the RFP is relatively simple process, the size of the reduced pattern relies highly on the duty ratio of the amount of photoresist. Therefore, in a preformed contact hole region, the size of the reduced pattern increases when the amount of photoresist flow is large, and decreases when the amount of photoresist flow is small. As a result, a uniform pattern cannot be obtained in the region wherein various patterns of different amount of photoresist coexist.

Even when thermal energy is uniformly transmitted during a thermal process, the amount of photoresist flow is relatively larger in a lower portion than in an upper or middle portion, thereby resulting in cracking of the upper portion of the pattern (b′>b″).

Meanwhile, the critical dimension of the pattern 16 generated by the RFP is reduced comparing to the initial critical dimension (a) relative to the bottom critical dimension (b″). However, when the underlying layer 12 is etched using the pattern 16 as an etching mask, the critical dimension of the pattern is tends to increase (b″<c′).

Therefore, conventional RFP has a high etching bias, resulting in the degradation of process margins.

### SUMMARY OF THE DISCLOSURE

The disclosure provides a method for preparing a photoresist pattern which improves etching bias and pattern profiling, thereby enhancing process margins by effectively reducing critical dimensions of a photoresist pattern.

### BRIEF DESCRIPTION OF THE DRAWINGS

For more complete understanding of the invention, reference should be made to the following detailed description and accompanying drawings wherein:

FIG. 1 is a cross-sectional diagram illustrating a method for forming a fine pattern by a conventional resist flow process.

FIG. 2a to FIG. 2c are a cross-sectional diagram illustrating a disclosed method for forming a fine pattern.

FIG. 3 is a photograph illustrating a fine pattern obtained from Comparative Example 1.

FIG. 4 is a photograph illustrating a fine pattern obtained from Comparative Example 2.

FIG. 5 is a photograph illustrating a first photoresist pattern obtained from Example 1.

FIG. 6 is a photograph illustrating a second photoresist pattern obtained from Example 1.

FIG. 7 is a photograph illustrating the second photoresist pattern obtained from Example 2.

FIG. 8 is a photograph illustrating the second photoresist pattern obtained from Example 3.

FIG. 9 is a photograph illustrating an etched underlying layer obtained from Comparative Example 3.

FIG. 10 is a photograph illustrating an etched underlying layer obtained from Example 4.

The specification, drawings and examples are intended to be illustrative, and are not intended to limit this disclosure to the specific embodiments described herein.

### DETAILED DESCRIPTION OF PREFERRED EMBODIMENTS

The disclosure provides a method for forming a photoresist pattern, which includes spraying a composition containing water and a surfactant and applying thermal energy to the pattern. The method preferably includes the steps of:

(a) coating a photoresist composition on an underlying layer formed on a semiconductor substrate to form a photoresist film;

(b) soft-baking the photoresist film;

(c) exposing the photoresist film to light;

(d) post-baking the exposed photoresist film;

(e) developing the exposed and post-baked photoresist film to obtain a first photoresist pattern;

(f) performing a RFP onto the first photoresist pattern to obtain a second photoresist pattern, and

spraying an aqueous composition containing water and a surfactant at least once between at least one pair of steps (a) and (b), (b) and (c), and (c) and (d).

Step (c) is preferably performed using a light source selected from KrF (248 nm), ArF (193 nm), VUV (157 nm), EUV (13 nm), E-beam, X-ray, and ion beam, and the exposing step is preferably performed at an exposing energy ranging from about 0.1 mJ/cm² to about 50 mJ/cm².

Preferably, the soft-baking and post-baking steps are performed at a temperature ranging from 50° C. to 150° C. for about 30 seconds to about 120 seconds, respectively.

In step (f), thermal energy is applied at a glass transition or higher temperature of the photoresist resin in the photoresist composition, thereby causing the photoresist pattern to flow. Therefore, the temperature condition can vary depending on the types of the photoresist resin, preferably at a temperature ranging from 120° C. to 200° C. for about 30 seconds to about 120 seconds.

After step (f), the method may further include the step (g) of etching the underlying layer using the second photoresist pattern as an etching mask to form an underlying layer pattern.

The photoresist pattern and the underlying pattern can be contact hole patterns or L/S (line and space) patterns, respectively.

Although any suitable surfactant can be used, a compound represented by Formula 1 is preferable for a surfactant of the aqueous composition.

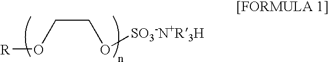

wherein R and R′ are individually H, C₁-C₂₀ alkyl and C₆-C₂₀ (alkyl)aryl; and

n is an integer ranging from 10 to 300.

The R and R′ of the compound represented by Formula 1 preferably is selected from methyl, ethyl, propyl, butyl, octyl, octylphenyl, nonyl, nonylphenyl, decyl, decylphenyl, undecyl, undecylphenyl, dodecyl, and dodecylphenyl.

Alternatively, a nonionic surfactant can be used instead of the compound of Formula 1.

Preferably, the amount of the surfactant in the aqueous composition is in the range of about 0.001 parts to about 10 parts by weight based on 100 parts by weight of water.

The aqueous composition can further contain one or more compounds selected from alcohol compounds, basic compounds and mixtures thereof.

The alcohol compound is preferably C₁-C₁₀ alkyl alcohol or C₃-C₁₀ alkoxyalkyl alcohol and is highly preferably at least one alcohol selected from the group consisting of methanol, ethanol, propanol, isopropanol, n-butanol, sec-butanol, t-butanol, 1-pentanol, 2-pentanol, 3-pentanol, 2,2-dimethyl-1-propanol, 2-methoxyethanol, 2-(2-methoxyethoxy)ethanol, 1-methoxy-2-propanol and 3-methoxy-1,2-propandiol, and mixtures thereof.

The basic compound can be any suitable organic compounds preferably having a pH of 7 to 12. Preferably, the basic compound is at least one compouns selected from the group consisting of N-methyl-2-pyrrolidone, triethylamine, triethanolamine, 15-crown-5,18-crown-6, ethylene glycol, diethylene glycol, triethylene glycol, and tetraethylene glycol, and mixtures thereof.

Preferably, the amount of alcohol compound and basic compound in the aqueous composition are in a range of about 0.001 parts to about 10 parts by weight based on 100 parts by weight of water, respectively.

The principle of the invention is as follows:

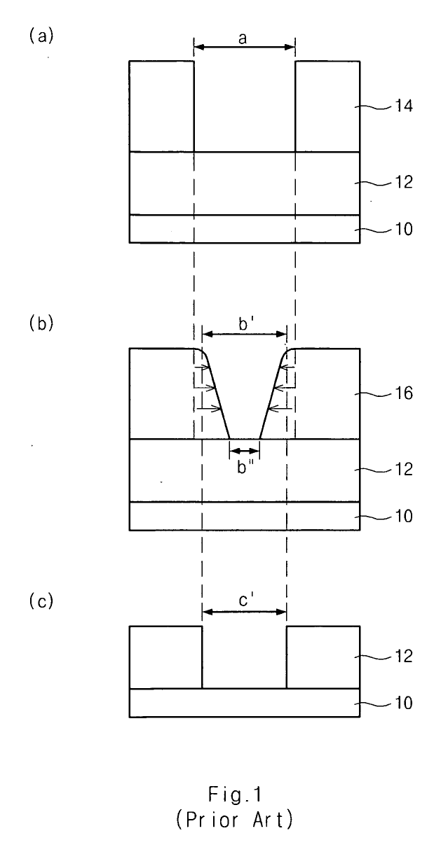

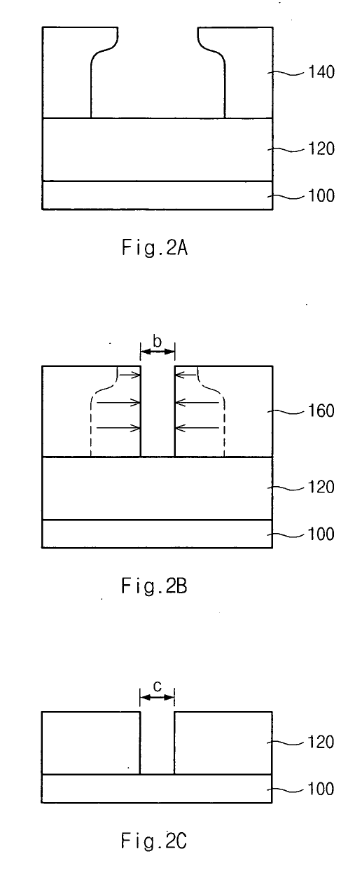

FIG. 1(a) shows a conventional photoresist pattern obtained after exposing and developing steps. When the aqueous composition is sprayed onto the pattern before the developing step, a T-topping phenomenon occurs on an upper portion of a photoresist pattern 140 as shown in FIG. 2a. That is, when the aqueous composition is sprayed before the soft-baking step after coating the photoresist composition or before the exposing step after the soft-baking step, a photoacid generator remained on the upper portion of the photoresist film is washed out, so that the pattern 140 as shown in FIG. 2a is obtained because the acid concentration of the upper portion decreases throughout the exposing, post-baking and developing steps. Even when the aqueous composition is sprayed after the exposing step and before the post-baking step, the acid remained on the upper portion of the photoresist film is washed out, so that the pattern 140 as shown in FIG. 2a is also obtained.

When thermal energy is applied to a substrate 100 having the pattern as shown in FIG. 2a at a temperature above the glass transition temperature of the photoresist resin in the photoresist composition, the photoresist pattern 140 follows, so that the overall pattern is vertically formed and the distance between the patterns decreases. The rate of flow in the middle and lower portion of the pattern is faster than that of the T-topped upper portion, so that the critical dimension is uniformly reduced after the flowing is completed (see FIG. 2b). Meanwhile, the final critical dimension of the underlying layer pattern (c) was obtained when an etching process was performed using the uniform photoresist pattern 160 as an etching mask and was found nearly the same as the critical dimension of the photoresist pattern (b) (see FIG. 2c).

### EXAMPLES

The invention will be described in more detail by referring to examples below, which are not intended to limit the present invention.

### Comparative Example 1

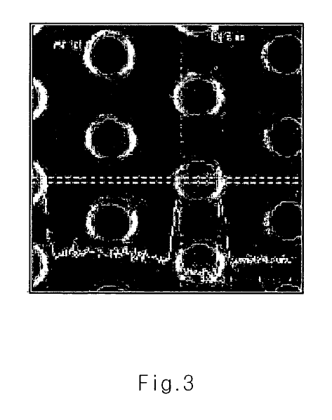

An ArF photoresist composition (Kumho Chemicals Inc., A52T3) was coated at a thickness of 2,400 Å on a semiconductor substrate. The resulting structure was soft-baked at 110° C., and then exposed to light using ArF scanner, 0.85 NA. After that, the resulting structure was post-baked at 120° C., and developed using 2.38 wt % tetramethylammonium hydroxide (TMAH) aqueous solution to obtain a photoresist pattern having an initial critical dimension (DICD; Develop Inspection Critical Dimension) of 115 nm (see FIG. 3).

### Comparative Example 2

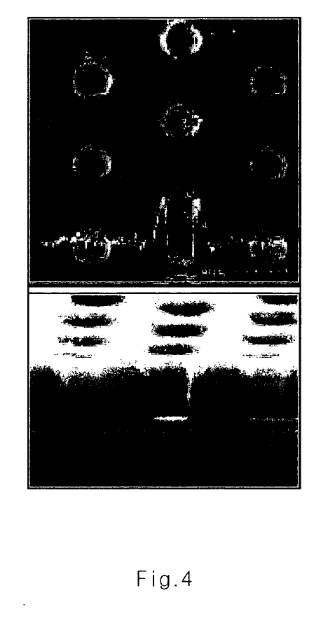

Thermal energy was applied to the pattern obtained from Comparative Example 1 at 153° C. for 60 seconds to flow the pattern, thereby obtaining a photoresist pattern having an average critical dimension of 82.5 nm. The critical dimension of the pattern in this example was smaller than that of the initial critical dimension of Comparative Example 1 (115 nm). However, the lower portion flowed more than the upper portion, so that the critical dimension of the upper portion of the pattern was larger than that of the lower portion (see FIG. 4).

### Example 1

### Treatment of Aqueous Solution after Exposing and Before Post-Baking Steps

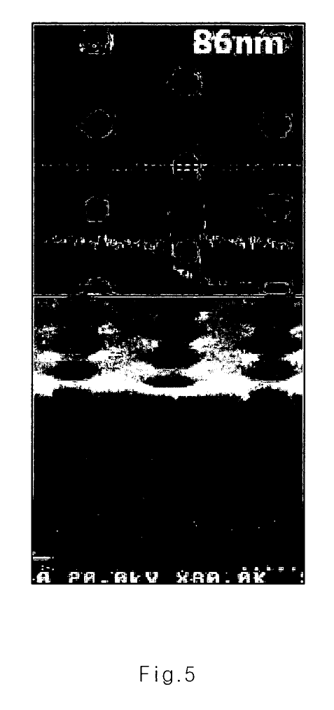

An ArF photoresist composition (Kumho Chemicals Inc., A52T3) was coated at a thickness of 2,400 Å on a semiconductor substrate. The resulting structure was soft-baked at 110° C., and exposed to light using ArF scanner, 0.85 NA. Then, 75 ml of aqueous solution ANTICOL (produced by Youngchang Chemical Co., LTD.) was sprayed at 30 rpm for 3 seconds, and the resultant was post-baked at 120° C. Thereafter, the resulting structure was developed using 2.38 wt % TMAH aqueous solution to obtain a photoresist pattern having an average critical dimension critical dimension of 86 nm (see FIG. 5).

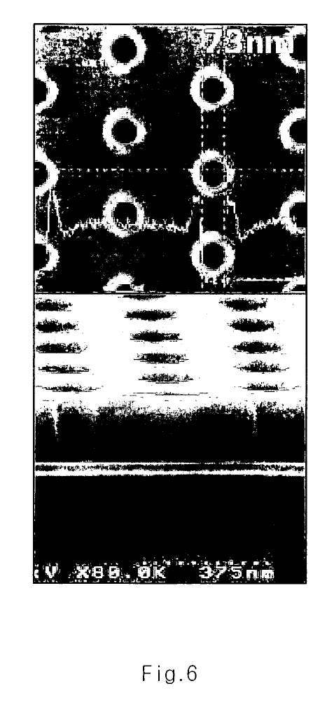

Thermal energy was applied to the pattern at 153° C. for 60 seconds to flow the pattern, thereby obtaining the second photoresist pattern having an average critical dimension of 73 nm (see FIG. 6).

FIG. 5 shows the T-topping phenomenon on the upper portion of the first photoresist pattern, and FIG. 6 shows that the flowing at the lower portion of the T-top occurs, so that the initial critical dimension is uniformly reduced into a vertical profile.

### Example 2

### Treatment of Aqueous Solution after Soft-Baking and Before Exposing Steps

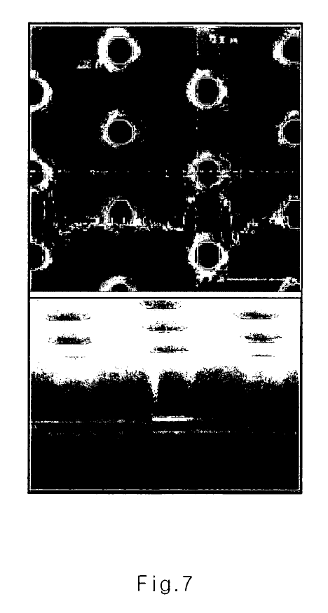

The procedure of Example 1 was repeated except that the aqueous solution (ANTICOL) was treated after soft-baking and before exposing steps, thereby obtaining a photoresist pattern having an average critical dimension of 74.2 nm (see FIG. 7).

### Example 3

### Treatment of Aqueous Solution after Coating of Photoresist Composition and Before Soft-Baking Steps

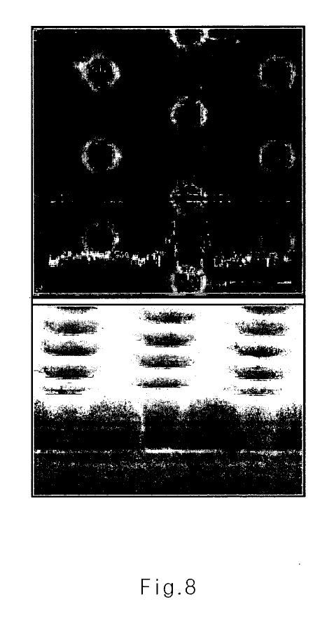

The same procedure of Example 1 was repeated except that the aqueous solution (ANTICOL) was treated after coating the photoresist composition and before the soft-baking step, thereby obtaining a photoresist pattern having an average critical dimension of 77.4 nm (see FIG. 8).

As a result of the Examples 1 to 3, it was found that the critical dimension of the second photoresist patterns using the method of the invention was reduced uniformly.

### Example 4

### Etching Bias Experiment

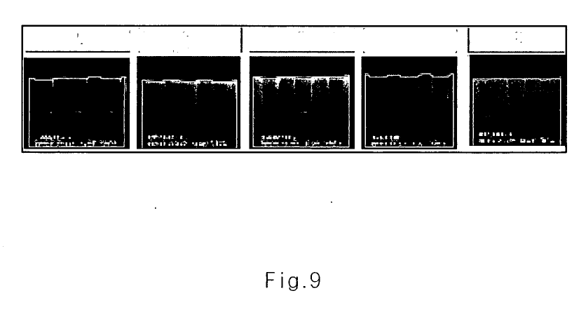

The aqueous solution was treated under the same conditions of the preceding inventive examples, and thermal energy was applied to obtain various types of patterns. The underlying layer was etched using the patterns as an etching mask. The result is shown in FIG. 9 and Table 1.

### Comparative Example 3

### Etching Bias Experiment

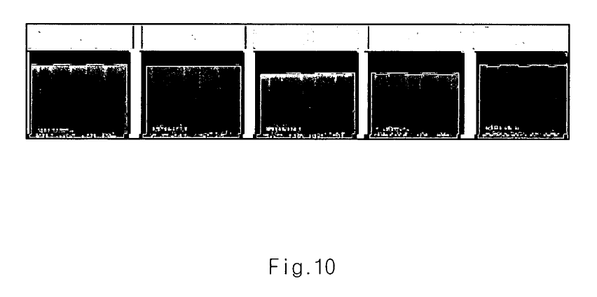

Under the conditions of Comparative Example 2, a resist flow process was performed to obtain various types of pattern, and the underlying layer was etched using the patterns as an etching mask. The result was shown in FIG. 10 and Table 1.

TABLE 1

| | Item | Average | 3σ | L | B | C | T | R | Etching bias |
|---|---|---|---|---|---|---|---|---|---|
| Comparative | DICD | 83.40 | 2.88 | 83.00 | 84 | 79 | 87 | 84 | 11.7 |
| Example 3 | top FICD | 142.91 | 5.91 | 147.70 | 139.35 | 134.75 | 149.00 | 143.75 | |
| | btm FICD | 95.10 | 10.35 | 95.70 | 102.60 | 78.15 | 104.30 | 94.75 | |
| | depth | 241.79 | 10.64 | 244.35 | 240.75 | 245.05 | 224.85 | 253.95 | |
| Example 4 | DICD | 73.60 | 6.27 | 78.00 | 73.00 | 63.00 | 78.00 | 76.00 | 0.80 |
| | top FICD | 119.24 | 11.76 | 125.00 | 134.10 | 106.30 | 122.55 | 108.25 | |
| | btm FICD | 72.80 | 11.03 | 80.60 | 84.80 | 58.95 | 75.85 | 63.80 | |
| | depth | 241.13 | 9.57 | 250.30 | 235.40 | 238.70 | 251.65 | 229.60 | |

DICD: Develop Inspection Critical Dimension
FICD: Final Inspection Critical Dimension
btm: bottom
unit: nm

Above Table 1 can be summarized as the following Table 2.

TABLE 2

| | DICD | CD after | FICD | Reduced | Etching |
|---|---|---|---|---|---|
| | (nm) | flowing (nm) | (nm) | width (nm) | bias (nm) |
| Comparative | 115 | 83.4 | 95.1 | 20 | 11.7 |
| Example 3 | | | | | |
| Example 4 | 115 | 73.6 | 72.8 | 42 | 0.8 |

As shown in Tables 1 and 2, it is shown that the etching bias is extremely small when the method of the present invention is used.

As described above, according to the disclosed process, the aqueous solution is coated during a pattern formation process to obtain a first photoresist pattern having a T-top on the upper portion of the pattern. Then, thermal energy is applied to the pattern, thereby effectively reducing a critical dimension of the pattern uniformly. In addition, since the critical dimension of the pattern is scarcely changed after etching of the underlying layer, the etching bias is extremely small and the process margin becomes improved.

What is claimed is:

1. A method for forming a photoresist pattern comprising the steps of:
(a) coating a photoresist composition on an underlying layer formed on a semiconductor substrate to form a photoresist film;
(b) soft-baking the photoresist film;
(c) exposing the photoresist film to light;
(d) post-baking the exposed photoresist film;
(e) developing the exposed and post-baked photoresist film to obtain a first photoresist pattern;
(f) performing a resist flow process (RFP) onto the first photoresist pattern to obtain a second photoresist pattern, and
spraying an aqueous composition comprising water and a surfactant at least once between at least one pair of steps (a) and (b), (b) and (c), and (c) and (d).

2. The method of claim 1, wherein the amount of the surfactant in the aqueous composition is in a range of about 0.001 parts to about 10 parts by weight based on 100 parts by weight of water.

3. The method of claim 1, wherein the aqueous composition further comprises a compound selected from the group consisting of alcohol compounds, basic compounds, and mixtures thereof.

4. The method of claim 3, wherein the alcohol compound present in the aqueous composition is in a range of about 0.001 parts to about 10 parts by weight based on 100 parts by weight of water.

5. The method of claim 3, wherein the basic compound present in the aqueous composition is in a range of about 0.001 to about 10 parts by weight based on 100 parts by weight of water.

6. The method of claim 1, comprising performing step (b) using a light source selected from the group consisting of KrF (248 nm), ArF (193 nm), VUV (157 nm), EUV (13 nm), E-beam, X-ray, and ion beam.

7. The method of claim 1, comprising performing the respective soft-baking and post-baking steps at a temperature ranging from 50° C. to 150° C. for about 30 seconds to about 120 seconds.

8. The method of claim 1, wherein the photoresist composition contains a photoresist resin and the method comprises performing step (f) at a glass transition or higher temperature of the photoresist resin.

9. The method of claim 8, comprising performing step (f) at a temperature ranging from 120° C. to 200° C. for about 30 seconds to about 120 seconds.

10. The method of claim 1, further comprising (g) etching the underlying layer using the second photoresist pattern as an etching mask to form an underlying layer pattern after step (f).

11. The method of claim 1, wherein the photoresist pattern and the underlying layer pattern are contact hole patterns or L/S (line and space) patterns, respectively.

12. The method of claim 10, wherein the photoresist pattern and the underlying layer pattern are contact hole patterns or L/S (line and space) patterns, respectively.
